(19) United States
(12) Patent Application Publication
(10) Pub. No.: US 2025/0098504 A1
(43) Pub. Date: Mar. 20, 2025

(54) DISPLAY DEVICE

(71) Applicant: Samsung Display Co., Ltd., Yongin-si (KR)

(72) Inventors: KYEONGJONG KIM, Yongin-si (KR); KYUNGHEE LEE, Yongin-si (KR)

(73) Assignee: Samsung Display Co., Ltd., Yongin-si (KR)

(21) Appl. No.: 18/776,761

(22) Filed: Jul. 18, 2024

(30) Foreign Application Priority Data
Sep. 19, 2023 (KR) 10-2023-0124915

(51) Int. Cl. H10K 59/80; H10K 59/126; H10K 59/38; H10K 102/00

(52) U.S. Cl. CPC H10K 59/8792; H10K 59/126; H10K 59/38; H10K 2102/351

(57) ABSTRACT

A display device includes a display panel divided into a light-emitting region, which emits light, and a non-light-emitting region adjacent to the light-emitting region, and an overcoat layer disposed on the display panel. The overcoat layer includes a first portion overlapping the non-light-emitting region in a plan view and including a first dye, and a second portion overlapping the light-emitting region in a plan view and including a first material obtained by degrading at least a portion of the first dye.

### CROSS-REFERENCE TO RELATED APPLICATIONS

This application claims priority to and benefits of Korean Patent Application No. 10-2023-0124915 under 35 U.S.C. § 119, filed on Sep. 19, 2023, in the Korean Intellectual Property Office (KIPO), the entire contents of which are incorporated herein by reference.

### BACKGROUND

### 1. Technical Field

The disclosure herein relates to a display device with improved display efficiency.

### 2. Description of the Related Art

Various display devices used for multimedia devices such as a television, a mobile phone, a tablet computer, and a game console are being developed. A display device may include various optical functional layers in order to provide a color image with excellent quality to a user.

Studies are recently being conducted on a thin display device in order to achieve various types of display devices such as a display device including a curved surface, a rollable display device, or a foldable display device. A thin display device may be achieved by reducing the number of optical functional layers and by including an optical functional layer having various functions.

### SUMMARY

The disclosure provides a display device with improved optical properties by reducing reflection of external light and improving display efficiency.

According to an embodiment of the disclosure, a display device may include a display panel divided into a light-emitting region which emits light, and a non-light-emitting region adjacent to the light-emitting region; and an overcoat layer disposed on the display panel. The overcoat layer may include a first portion overlapping the non-light-emitting region in a plan view and including a first dye, and a second portion overlapping the light-emitting region in a plan view and including a first material obtained by degrading at least a portion of the first dye.

In an embodiment, the first material may be obtained by photodegrading at least a portion of the first dye by ultraviolet rays.

In an embodiment, the first dye may include a chromophore, and the first material may be obtained by destroying at least a portion of the chromophore by the ultraviolet rays.

In an embodiment, an absorbance of the first portion may be greater than an absorbance of the second portion with respect to visible light.

In an embodiment, a weight percent of the first dye with respect to a total weight of the first portion may be in a range of about 0.1 wt % to about 5 wt %,

In an embodiment, the first dye may have an absorption wavelength peak in a range of about 530 nm to about 600 nm.

In an embodiment, the first dye may include at least one of an anthraquinone-based compound, a phthalocyanine-based compound, an azo-based compound, a perylene-based compound, a xanthene-based compound, a diimmonium-based compound, a dipyrromethene-based compound, a tetraazaporphyrin-based compound, a porphyrin-based compound, a squarylium-based compound, an oxazine-based compound, a triarylmethane-based compound, and a cyanine-based compound.

In an embodiment, the overcoat layer may have a thickness in a range of about 1 μm to about 15 μm.

In an embodiment, the overcoat layer may further include a pigment. A weight percent of the pigment with respect to a total weight of the overcoat layer may be in a range of about 1 wt % to about 50 wt %.

In an embodiment, the display device may further include an ultraviolet ray blocking layer disposed on the overcoat layer and overlapping the non-light-emitting region in a plan view.

In an embodiment, the ultraviolet ray blocking layer may include a light absorber or a light stabilizer with respect to ultraviolet rays.

In an embodiment, the display panel may include a light-emitting element that emits first-color light, the light-emitting region may include a first light-emitting region, a second light-emitting region and a third light-emitting region which are spaced apart from each other in a plan view, the first light-emitting region may emit second-color light different from the first-color light, the second light-emitting region may emit third-color light different from the first-color light and the second-color light, and the third light-emitting region may transmit the first-color light.

In an embodiment, the display device may further include a light control layer disposed between the display panel and the overcoat layer. The light control layer may include a first light control part that overlaps the first light-emitting region in a plan view and converts the first-color light into the second-color light, and a second light control part that overlaps the second light-emitting region in a plan view and converts the first-color light into the third-color light.

In an embodiment, the display device may further include a color filter layer disposed between the display panel and the light control layer. The color filter layer may include a first filter that overlaps the first light-emitting region in a plan view and blocks the first-color light and the third-color light, a second filter that overlaps the second light-emitting region in a plan view and blocks the first-color light and the second-color light, and a third filter that overlaps the third light-emitting region in a plan view and blocks the second-color light and the third-color light.

In an embodiment, the third filter may entirely overlap the non-light-emitting region in a plan view.

In an embodiment, in a plan view, the first filter may not overlap the second filter.

In an embodiment, the display device may further include a low-refractive-index layer disposed between the light control layer and the color filter layer; and an anti-reflection layer disposed on the color filter layer.

In an embodiment of the disclosure, a display device may include a display panel divided into a light-emitting region which emits light and a non-light-emitting region adjacent to the light-emitting region, and an overcoat layer disposed on the display panel, and including a first portion overlapping the non-light-emitting region in a plan view and a second portion overlapping the light-emitting region in a plan view, The overcoat layer may include a first dye, and a weight percent of the first dye with respect to a total weight of the first portion may be greater than a weight percent of the first dye with respect to a total weight of the second portion.

In an embodiment, the weight percent of the first dye with respect to the total weight of the second portion may be less than or equal to about 0.1 wt %.

### BRIEF DESCRIPTION OF THE DRAWINGS

The accompanying drawings are included to provide a further understanding of the disclosure, and are incorporated in and constitute a part of this specification. The drawings illustrate embodiments of the disclosure and, together with the description, serve to explain principles of the disclosure. In the drawings:

FIG. 1 is a perspective view illustrating a display device according to an embodiment;

FIG. 2 is a plan view illustrating a portion of a display device according to an embodiment;

FIG. 3 is a schematic cross-sectional view of a display device according to an embodiment;

FIG. 4 is an enlarged schematic cross-sectional view of a portion of a display device according to an embodiment;

FIGS. 5A to 5C are schematic cross-sectional views of a display device according to an embodiment;

FIGS. 6A and 6B are schematic cross-sectional views sequentially illustrating some operations of a method of manufacturing a display device according to an embodiment;

FIGS. 7A and 7B are schematic cross-sectional views of a display device according to Comparative Example;

FIG. 8 is a graph showing light transmittance values according to Example and Comparative Example 1; and

FIG. 9 is a graph showing color coordinates according to Example and Comparative Example 2.

### DETAILED DESCRIPTION OF THE EMBODIMENTS

Hereinafter, embodiments of the disclosure will be described with reference to the accompanying drawings.

When an element, such as a layer, is referred to as being “on,” “connected to,” or “coupled to” another element or layer, it may be directly on, connected to, or coupled to the other element or layer or intervening elements or layers may be present. When, however, an element or layer is referred to as being “directly on,” “directly connected to,” or “directly coupled to” another element or layer, there are no intervening elements or layers present. To this end, the term “connected” may refer to physical, electrical, and/or fluid connection, with or without intervening elements.

Like reference numerals or symbols refer to like elements throughout. Also, in the drawings, the thickness, the ratio, and the dimension of the elements are exaggerated for effective description of the technical contents. The term “and/or” includes all combinations of one or more of the associated listed elements.

Although the terms first, second, etc., may be used to describe various elements, these elements should not be limited by these terms. These terms are only used to distinguish one element from another element. For example, a first element may be referred to as a second element, and similarly, a second element may also be referred to as a first element without departing from the scope of the disclosure. The singular forms include the plural forms as well, unless the context clearly indicates otherwise.

Spatially relative terms, such as “beneath,” “below,” “under,” “lower,” “above,” “upper,” “over,” “higher,” “side” (e.g., as in “sidewall”), and the like, may be used herein for descriptive purposes, and, thereby, to describe one elements relationship to another element(s) as illustrated in the drawings. Spatially relative terms are intended to encompass different orientations of an apparatus in use, operation, and/or manufacture in addition to the orientation depicted in the drawings. For example, if the apparatus in the drawings is turned over, elements described as “below” or “beneath” other elements or features would then be oriented “above” the other elements or features. Thus, the exemplary term “below” can encompass both an orientation of above and below. Furthermore, the apparatus may be otherwise oriented (e.g., rotated 90 degrees or at other orientations), and, as such, the spatially relative descriptors used herein interpreted accordingly.

The terminology used herein is for the purpose of describing particular embodiments and is not intended to be limiting. As used herein, the singular forms, “a,” “an,” and “the” are intended to include the plural forms as well, unless the context clearly indicates otherwise. Moreover, the terms “comprises,” “comprising,” “includes,” and/or “including,” when used in this specification, specify the presence of stated features, integers, steps, operations, elements, components, and/or groups thereof, but do not preclude the presence or addition of one or more other features, integers, steps, operations, elements, components, and/or groups thereof.

“About” or “approximately” as used herein is inclusive of the stated value and means within an acceptable range of deviation for the particular value as determined by one of ordinary skill in the art, considering the measurement in question and the error associated with measurement of the particular quantity (i.e., the limitations of the measurement system). For example, “about” may mean within one or more standard deviations, or within +30%, 20%, 10%, 5% of the stated value.

In this specification, it will be understood that “being directly disposed” means that there are no intervening layers, films, regions, plates, or the like between a portion of layers, films, regions, plates, or the like and another portion. For example, “being directly disposed” may mean to be disposed between two layers or two members without using an additional member such as an adhesive member or like.

In the specification and the claims, the phrase “at least one of” is intended to include the meaning of “at least one selected from the group of” for the purpose of its meaning and interpretation. For example, “at least one of A and B” may be understood to mean “A, B, or A and B.” In the specification and the claims, the term “and/or” is intended to include any combination of the terms “and” and “or” for the purpose of its meaning and interpretation. For example, “A and/or B” may be understood to mean “A, B, or A and B.” The terms “and” and “or” may be used in the conjunctive or disjunctive sense and may be understood to be equivalent to “and/or.”

Unless otherwise defined or implied herein, all terms (including technical and scientific terms) used have the same meaning as commonly understood by those skilled in the art to which this disclosure pertains. It will be further understood that terms, such as those defined in commonly used dictionaries, should be interpreted as having a meaning that is consistent with their meaning in the context of the relevant art and should not be interpreted in an ideal or excessively formal sense unless clearly defined in the specification.

Hereinafter, a display device according to an embodiment of the disclosure will be described with reference to the accompanying drawings.

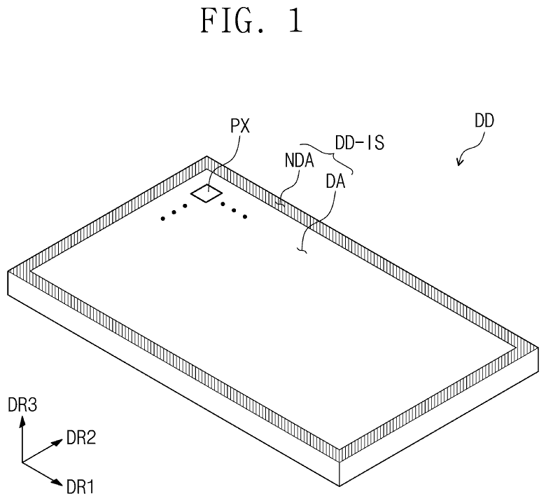

FIG. 1 is a perspective view illustrating a display device according to an embodiment.

A display device DD according to an embodiment may be activated in response to an electrical signal. For example, the display device DD may be a television, an outdoor billboard, a portable electronic device, a tablet computer, a car navigation unit, a game console, a personal computer, a laptop computer, or a wearable device, but the disclosure is not limited thereto.

The display device DD may display an image (or video) through a display surface DD-IS. The display surface DD-IS may be parallel to a plane defined by a first direction axis DR1 and a second direction axis DR2. The display surface DD-IS may include a display region DA and a non-display region NDA.

A pixel PX may be disposed in the display region DA and may not be disposed in the non-display region NDA. The non-display region NDA may be defined along a side of the display region DA. The non-display region NDA may surround the display region DA. However, the disclosure is not limited thereto. The non-display region NDA may be omitted, or may also be disposed on only one side of the display region DA.

FIG. 1 schematically illustrates the display device DD provided with a flat display surface DD-IS, but the disclosure is not limited thereto. The display device DD may include a curved display surface or a three-dimensional display surface. The three-dimensional display surface may include multiple display regions which respectively face different directions.

A thickness direction of the display device DD may be parallel to a third direction axis DR3 which is a normal direction of the plane defined by the first direction axis DR1 and the second direction axis DR2. The directions indicated by the first to third direction axes DR1, DR2, and DR3 illustrated herein have a relative concept, and may thus be changed to other directions. In addition, the directions indicated by the first to third direction axes DR1, DR2, and DR3 may be referred to as first to third directions, and may be denoted as the same reference numerals or symbols.

In this specification, an upper surface (or front surface) and a lower surface (or rear surface) of each member constituting the display device DD may be defined based on the third direction axis DR3. More specifically, in one member, among two surfaces facing each other based on the third direction axis DR3, a surface relatively adjacent to the display surface DD-IS may be defined as a front surface (or upper surface), and a surface relatively spaced apart from the display surface DD-IS may be defined as a rear surface (or lower surface). In this specification, an upper part and a lower part may be defined based on the third direction axis DR3. The upper part may be defined as a direction of getting closer to the display surface DD-IS, and the lower part may be defined as a direction of getting farther away from the display surface DD-IS.

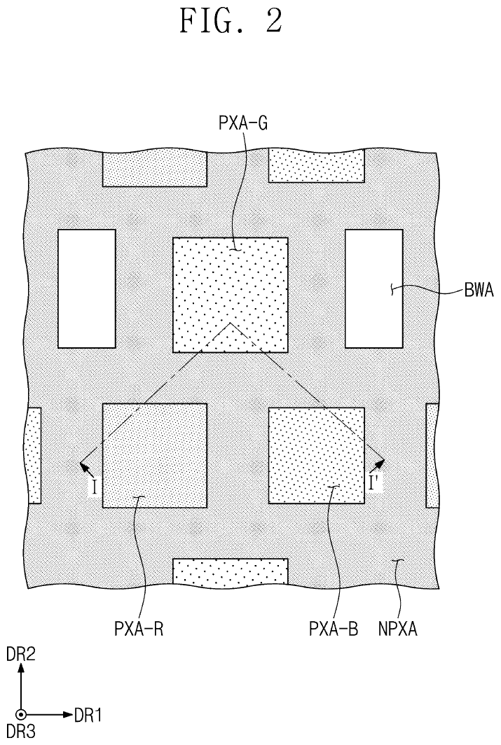

FIG. 2 is an enlarged plan view of a portion of a display device DD according to an embodiment. FIG. 2 schematically illustrates a plane including three light-emitting regions PXA-R, PXA-B, and PXA-G, and a bank well region BWA adjacent thereto. The three light-emitting regions PXA-R, PXA-B, and PXA-G illustrated in FIG. 2 may be regions corresponding to pixels PX (see FIG. 1), and may be repeatedly arranged in the entire display region DA (see FIG. 1).

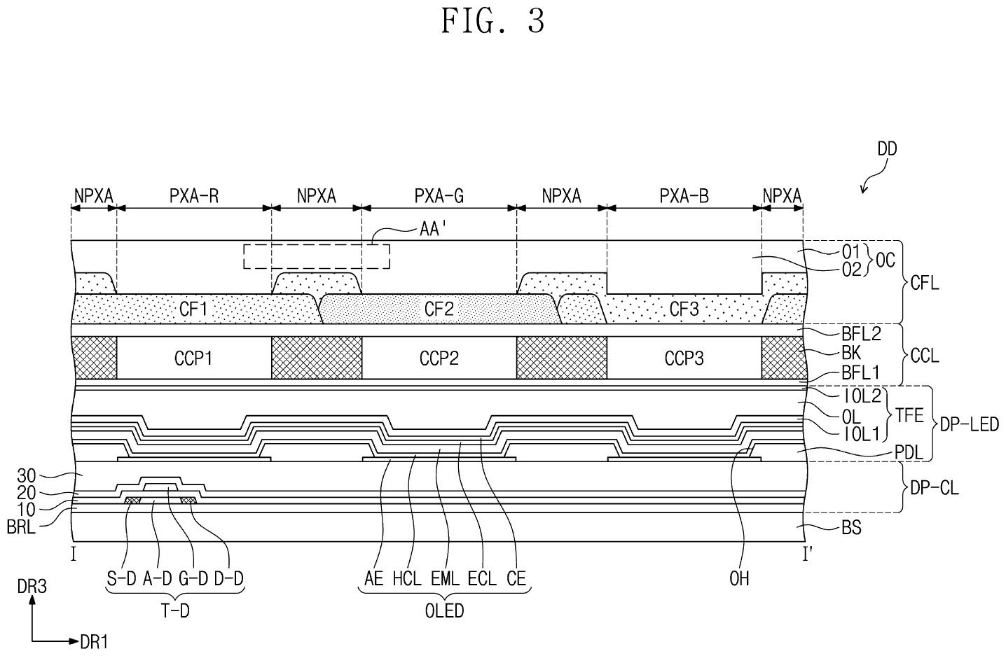

A non-light-emitting region NPXA may be disposed around the first to third light-emitting regions PXA-R, PXA-B, and PXA-G. The non-light-emitting region NPXA may define boundaries between the first to third light-emitting regions PXA-R, PXA-B, and PXA-G. The non-light-emitting region NPXA may surround the first to third light-emitting regions PXA-R, PXA-B, and PXA-G in a plan view. A structure, such as a pixel-defining film PDL (see FIG. 3), which prevents color-mixing between the first to third light-emitting regions PXA-R, PXA-B, and PXA-G may be disposed in the non-light-emitting region NPXA.

FIG. 2 schematically illustrates that the first to third light-emitting regions PXA-R, PXA-B, and PXA-G have a same planar shape and have different planar areas in a plan view, but the disclosure is not limited thereto. At least two light-emitting regions among the first to third light-emitting regions PXA-R, PXA-B, and PXA-G may have a same area. The areas of the first to third light-emitting regions PXA-R, PXA-B, and PXA-G may be set according to colors of emitted light. A light-emitting region which emits light of red color among primary colors may have the greatest area, and a light-emitting region which emits light of blue color may have the smallest area in a plan view.

FIG. 2 schematically illustrates that in a plan view, the first to third light-emitting regions PXA-R, PXA-B, and PXA-G each have a rectangular shape. However, the disclosure is not limited thereto. In another embodiment, the first to third light-emitting regions PXA-R, PXA-B, and PXA-G may each have another polygonal shape such as a rhombic or pentagonal shape. In another embodiment, the first to third light-emitting regions PXA-R, PXA-B, and PXA-G may each have a rectangular shape with rounded corners.

FIG. 2 schematically illustrates that the second light-emitting region PXA-G is disposed in a first row, and the first light-emitting region PXA-R and the third light-emitting region PXA-B are disposed in a second row. However, the disclosure is not limited thereto, and an arrangement of the first to third light-emitting regions PXA-R, PXA-B, and PXA-G may change variously. For example, the first to third light-emitting regions PXA-R, PXA-B, and PXA-G may be disposed in a same row.

One of the first to third light-emitting regions PXA-R, PXA-B, and PXA-G may emit first-color light, another one of the first to third light-emitting regions PXA-R, PXA-B, and PXA-G may emit second-color light different from the first-color light, and the other the first to third light-emitting regions PXA-R, PXA-B, and PXA-G may emit third-color light different from the first-color light and the second-color light. For example, the first light-emitting region PXA-R may emit red light, the second light-emitting region PXA-G may emit green light, and the third light-emitting region PXA-B may emit blue light.

The bank well region BWA may be defined in the display region DA (see FIG. 1). The bank well region BWA may be a region formed to prevent defects caused by a deposition error during a process which patterns multiple light control parts CCP1, CCP2, and CCP3 included in a light control layer CCL (see FIG. 3) to be described below. The bank well region BWA may be a region in which a portion of a bank BK (see FIG. 3) is removed. FIG. 2 schematically illustrates that two bank well regions BWA are formed adjacent to the second light-emitting region PXA-G, but the disclosure is not limited thereto. A shape and an arrangement of the bank well region BWA may change variously.

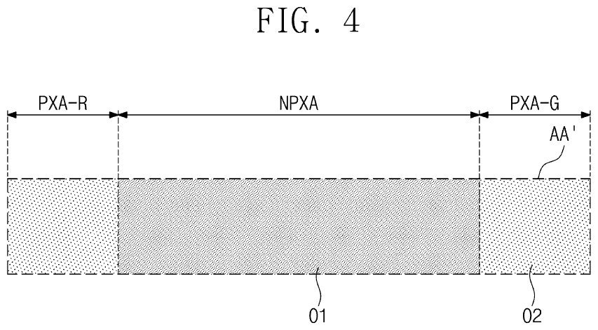

FIG. 3 is a schematic cross-sectional view of a display device according to an embodiment. FIG. 3 is a schematic cross-sectional view illustrating a portion corresponding to line I-I′ of FIG. 2. FIG. 4 is an enlarged schematic cross-sectional view of a partial region of a color filter layer according to an embodiment of the disclosure. In FIG. 4, an enlarged cross section corresponding to region AA′ of FIG. 3 is illustrated.

Referring to FIG. 3, the display device DD may include a base substrate BS, a circuit layer DP-CL dispose on an upper part of the base substrate BS, a light-emitting element layer DP-LED disposed on an upper part of the circuit layer DP-CL, a light control layer CCL disposed on an upper part of the light-emitting element layer DP-LED, and a color filter layer CFL disposed on an upper part of the light control layer CCL.

The base layer BS may be a member which provides a base surface on which the circuit layer DP-CL is disposed. The base layer BS may include a single layer or multiple layers. For example, the base substrate BS may include a three-layered structure of a polymer resin layer, an adhesive layer, and a polymer resin layer. For example, the polymer resin layer may include a polyimide-based resin. In another embodiment, the polymer resin layer may include at least one of an acrylate-based resin, a methacrylate-based resin, a polyisoprene-based resin, a vinyl-based resin, an epoxy-based resin, a urethane-based resin, a cellulose-based resin, a siloxane-based resin, a polyamide-based resin, and a perylene-based resin.

In this specification, a polyimide-based resin may be considered as including a functional group of polyimide. The description made above may also be similarly applied to the acrylate-based resin, the methacrylate-based resin, the polyisoprene-based resin, the vinyl-based resin, the epoxy-based resin, the urethane-based resin, the cellulose-based resin, the siloxane-based resin, the polyamide-based resin, and the perylene-based resin.

The circuit layer DP-CL may include a lower buffer layer BRL disposed on an upper part of the base substrate BS, a first insulating layer 10 disposed on an upper part of the lower buffer layer BRL, a second insulating layer 20 disposed on an upper part of the first insulating layer 10, and a third insulating layer 30 disposed on an upper part of the second insulating layer 20. For example, the lower buffer layer BRL, the first insulating layer 10, and the second insulating layer 20 may be inorganic layers, and the third insulating layer 30 may be an organic layer.

The circuit layer DP-CL may also include transistors T-D. The transistors T-D may each include an active A-D, a source S-D, a drain D-D, and a gate G-D. The active A-D, the source S-D, the drain D-D, and the gate G-D may be regions distinguished according to the doping concentration or conductivity of a semiconductor pattern. The active A-D, the source S-D, and the drain D-D may be disposed on an upper part of the lower buffer layer BRL, and the gate G-D may be disposed on an upper part of the first insulating layer 10. For example, the transistors T-D may be a switching transistor or a driving transistor for driving a light-emitting element OLED of the light-emitting element layer DP-LED. However, the transistors T-D are not limited thereto.

The light-emitting element layer DP-LED may include a pixel-defining film PDL having a pixel opening OH, and the light-emitting element OLED. The light-emitting element OLED may include a first electrode AE exposed by the pixel opening OH, a second electrode CE facing the first electrode AE, and a light-emitting layer EML disposed between the first electrode AE and the second electrode CE. The light-emitting element OLED may further include a hole transport region HCL disposed between the first electrode AE and the light-emitting layer EML, and an electron transport region ECL disposed between the light-emitting layer EML and the second electrode CE. The hole transport region may include at least one of a hole injection layer, a hole transport layer, and an electron blocking layer. The electron transport region may include at least one of an electron injection layer, an electron transport layer, and a hole blocking layer.

The first electrode AE may be an anode or a cathode. The first electrode AE may be a pixel electrode. The first electrode AE may be a transmissive electrode, a transflective electrode, or a reflective electrode. The second electrode CE may be a common electrode. The second electrode CE may be an anode or a cathode, but the disclosure is not limited thereto. For example, in case that the first electrode AE is an anode, the second electrode CE may be a cathode, and in case that the first electrode AE is a cathode, the second electrode CE may be an anode. The second electrode CE may be a transmissive electrode, a transflective electrode, or a reflective electrode.

The light-emitting layer EML may emit first-color light. For example, the light-emitting layer EML may generate blue color light. The light-emitting layer EML may generate light having a wavelength in a range of about 410 nm to about 480 nm. FIG. 3 schematically illustrates the light-emitting element OLED including one light-emitting layer EML, but the disclosure is not limited thereto, and in another embodiment, the light-emitting element OLED may include multiple light-emitting layers. For example, the light-emitting element OLED may have a tandem structure.

The light-emitting layer EML may include a fluorescent or phosphorescent material. For example, the light-emitting layer EML may include an anthracene derivative, a pyrene derivative, a fluoranthene derivative, a chrysene derivative, a dihydrobenzanthracene derivative, or a triphenylene derivative. In another embodiment, the light-emitting layer EML may include a metal organic complex as a light-emitting material.

FIG. 3 schematically illustrates that the light-emitting layer EML is provided as a common layer and overlaps the light-emitting regions PXA-R, PXA-G, and PXA-B, and the non-light-emitting region NPXA in a plan view, but the disclosure is not limited thereto. The light-emitting layer EML may be patterned in the pixel opening OH, and be provided to overlap each of the light-emitting regions PXA-R, PXA-G, and PXA-B and not to overlap the non-light-emitting region NPXA in a plan view.

The pixel opening OH of the pixel-defining film PDL may expose at least a portion of the first electrode AE. The pixel-defining film PDL may overlap the non-light-emitting region NPXA, and not overlap the light-emitting regions PXA-R, PXA-G, and PXA-B in a plan view. The pixel-defining film PDL may include an organic material. For example, the pixel-defining film PDL may be optically transparent. The pixel-defining film PDL may have a transmittance of greater than or equal to about 85% with respect to light having a wavelength in range of about 380 nm to about 780 nm.

In this specification, it will be understood that when a component overlaps another component, it is not limited to a case where the two components have the same area or shape in a plan view, and also may include a case where the two components have different areas and/or shapes. The plane is referred to as a plane perpendicular to a thickness direction.

The light-emitting element layer DP-LED may include a thin-film encapsulation layer TFE which protects the second electrode CE. The thin-film encapsulation layer TFE may include an organic material or an inorganic material. The thin-film encapsulation layer TFE may have a multi-layered structure in which an inorganic layer/an organic layer are repeated. In an embodiment, the thin-film encapsulation layer TFE may include a first inorganic encapsulation layer IOL1, an organic encapsulation layer OL, and a second inorganic encapsulation layer IOL2. The first and second inorganic encapsulation layers IOL1 and IOL2 may protect the light-emitting element OLED against external moisture, and the organic encapsulation layer OL may prevent a dent defect in the light-emitting element OLED due to foreign materials introduced during a manufacturing process. Although not illustrated, the display panel DP may further include a refractive index control layer on an upper side of the thin-film encapsulation layer TFE to improve light emission efficiencies.

The light control layer CCL may be disposed on the light-emitting element layer DP-LED. The light control layer CCL may include a light-converting material. The light-converting material may be quantum dots or phosphors. The light-converting material may convert a wavelength of provided light and emit the light. For example, the light control layer CCL may be a layer including quantum dots or phosphors.

The light control layer CCL may include multiple light control parts CCP1, CCP2, and CCP3. The light control parts CCP1, CCP2, and CCP3 may be spaced apart from each other. The light control layer CCL may include a first light control part CCP1 which converts the first-color light provided from the light-emitting element OLED into the second-color light, a second light control part CCP2 which converts the first-color light into the third-color light, and a third light control part CCP3 which transmits the first-color light.

The light control layer CCL may include banks BK disposed between the light control parts CCP1, CCP2, and CCP3 which are spaced apart from each other. FIG. 3 schematically illustrates that the banks BK do not overlap the light control parts CCP1, CCP2, and CCP3 in a plan view, but the disclosure is not limited thereto, and in another embodiment, edges of the light control parts CCP1, CCP2, and CCP3 may at least partially overlap the banks BK.

The bank BK may include a base resin and an additive. The base resin may be composed of resin composition generally referred to as a binder. The additive may include a coupling agent and/or a photoinitiator. The additive may further include a dispersant.

The bank BK may include a black coloring agent to block light. The bank BK may include a black pigment or a black dye mixed in a base resin. In an embodiment, the black coloring agent may include carbon black, or include a metal such as chromium or an oxide thereof.

The light control layer CCL may include a barrier layer BFL1. The barrier layer BFL1 may prevent infiltration of moisture and/or oxygen (hereinafter, referred to as ‘moisture/oxygen’). The barrier layer BFL1 may be disposed on the light control parts CCP1, CCP2, and CCP3 and block the light control parts CCP1, CCP2, and CCP3 from being exposed to moisture/oxygen. The barrier layer BFL1 may cover the light control parts CCP1, CCP2, and CCP3. An additional barrier layer BFL2 may be provided between the light control parts CCP1, CCP2, and CCP3 and filters CF1, CF2, and CF3.

The barrier layers BFL1 and BFL2 may include at least one inorganic layer. For example, the barrier layers BFL1 and BFL2 may include an inorganic material. For example, the barrier layers BFL1 and BFL2 may include silicon nitride, aluminum nitride, zirconium nitride, titanium nitride, hafnium nitride, tantalum nitride, silicon oxide, aluminum oxide, titanium oxide, tin oxide, cerium oxide, or silicon oxynitride, or include a metal foil having light transmittance. The barrier layers BFL1 and BFL2 may further include an organic layer. The barrier layers BFL1 and BFL2 may each have a single- or multi-layered structure.

In the display device DD according to an embodiment, the color filter layer CFL may be disposed on the light control layer CCL. For example, the color filter layer CFL may be disposed (e.g., directly disposed) on the light control layer CCL, and the additional barrier layer BFL2 may be omitted.

The color filter layer CFL may include filters CF1, CF2, and CF3, and an overcoat layer OC covering the filters CF1, CF2, and CF3.

The color filter layer CFL may include a first filter CF1 which transmits the second-color light, a second filter CF2 which transmits the third-color light, and a third filter CF3 which transmits the first-color light. For example, the first filter CF1 may be a red filter, the second filter CF2 may be a green filter, and the third filter CF3 may be a blue filter. The filters CF1, CF2, and CF3 may each include a polymer photosensitive resin, and a pigment or dye. The first filter CF1 may include a red pigment or dye, the second filter CF2 may include a green pigment or dye, and the third filter CF3 may include a blue pigment or dye. However, the disclosure is not limited thereto, and the third filter CF3 may not include a pigment or a dye. The third filter CF3 may include a polymer photosensitive resin and may not include a pigment or a dye. The third filter CF3 may be transparent. The third filter CF3 may be formed of a transparent photosensitive resin. For example, a portion of the third filter CF3 may include a blue pigment or dye, and another portion may be formed of a transparent photosensitive resin.

The first to third filters CF1, CF2, and CF3 may be disposed on a same layer to respectively correspond to the first light-emitting region PXA-R, the second light-emitting region PXA-G, and the third light-emitting region PXA-B. In the first light-emitting region PXA-R, the second light-emitting region PXA-G, and the third light-emitting region PXA-B, the first to third filters CF1, CF2, and CF3 may have substantially a same height from an upper surface of the light control layer CCL in the third direction DR3. However, the disclosure is not limited thereto. Unlike what is illustrated in FIG. 3, the first and second filters CF1 and CF2 may have substantially a same height in the first light-emitting region PXA-R and the second light-emitting region PXA-G, and the third filter CF3 may have a height different from the heights of the first and second filters CF1 and CF2 in the third light-emitting region PXA-B. For example, the height of the third filter CF3 in the third light-emitting region PXA-B may be relatively smaller than the heights of the first and second filters CF1 and CF2 which respectively disposed in the first light-emitting region PXA-R and the second light-emitting region PXA-G. In another embodiment, an upper surface of a portion of the third filter CF3 in the third light-emitting region PXA-B and an upper surface of a portion of the third filter CF3 in the non-light-emitting region NPXA may be arranged side by side, and the third filter CF3 may have substantially a same height in the light-emitting region PXA-B and the non-light-emitting region NPXA.

The first to third filters CF1, CF2, and CF3 may be disposed in at least a portion of the non-light-emitting region NPXA. For example, the first and second filters CF1 and CF2 may be disposed in a partial region of the non-light-emitting region NPXA, and the third filter CF3 may be disposed in an entire area the non-light-emitting region NPXA. In a plan view, the first and second filters CF1 and CF2 may not overlap each other. The first filter CF1 may be disposed to overlap a boundary of the second filter CF2 in a plan view, and the second filter CF2 may be disposed to overlap a boundary of the first filter CF1 in a plan view. However, the structure of the filters is not limited thereto. Unlike what is illustrated in FIG. 3, in a plan view, a boundary of the first filter CF1 and a boundary of the second filter CF2 may not overlap each other and be spaced apart from each other. The third filter CF3 may be disposed on the first and second filters CF1 and CF2 in the non-light-emitting region NPXA. For example, the first filter CF1 and/or the second filter CF2 may be disposed on the light control layer CCL in the non-light-emitting region NPXA, and the third filter CF3 may be disposed on the first filter CF1 and/or the second filter CF2 in the non-light-emitting region NPXA.

Although not illustrated, the color filter layer CFL may include a light blocking part (not illustrated). The light blocking part (not illustrated) may overlap boundaries of the adjacent filters CF1, CF2, and CF3 in a plan view. The light blocking part (not illustrated) may be disposed to correspond to the non-light-emitting region NPXA, and the first to third filters CF1, CF2, and CF3 may also be disposed to respectively correspond to the first light-emitting region PXA-R, the second light-emitting region PXA-G, and the third light-emitting region PXA-B. The light blocking part (not illustrated) may be disposed to be spaced apart from each other. The light blocking part (not illustrated) may be a black matrix which prevents light leakage. The light blocking part (not illustrated) may be formed from an organic light-blocking material or an inorganic light-blocking material which includes a black pigment or a black dye. The light blocking part (not illustrated) may define boundaries of the adjacent filters CF1, CF2, and CF3. In another embodiment, the light blocking part (not illustrated) may be formed as a blue filter.

The overcoat layer OC may cover a front surface of the display panel DP and protect the display panel DP. The overcoat layer OC may have a thickness in a range of about 1 micrometer to 15 micrometers. The overcoat layer OC may be an organic layer which protects the filters CF1, CF2, and CF3. The overcoat layer OC may include a photocurable organic material or a thermosetting organic material. However, the disclosure is not limited thereto, and the overcoat layer OC may include an inorganic material.

The overcoat layer OC may have a high light absorption rate in a specific wavelength range. The overcoat layer OC may include a pigment or a dye having a high light absorption rate in a specific wavelength range. In case that the overcoat layer OC includes a pigment, the overcoat layer OC may include a pigment in an amount in a range of about 1 wt % to about 50 wt % with respect to the total weight of the overcoat layer OC.

The overcoat layer OC may entirely overlap a light-emitting element layer DP-LED in a plan view. The overcoat layer OC may include a first portion O1 in the non-light-emitting region NPXA, and a second portion O2 in the light-emitting regions PXA-R, PXA-G, and PXA-B.

The first portion O1 may include a first dye. The first dye may have a high light absorption rate in a specific wavelength range. The first dye may be an organic material having a high light absorption rate in at least one visible light wavelength range. The first dye may include a chromophore which absorbs light having a specific visible light wavelength range. The first dye may be a material which absorbs light having a peak absorption wavelength in a wavelength range other than wavelength ranges of the first-color light, the second-color light, and the third-color light. For example, the first dye may be a material which absorbs light having a peak absorption wavelength in a wavelength range other than a wavelength range of the first-color light. In an embodiment, the first dye may have a peak absorption wavelength in a wavelength range of about 530 nm to about 600 nm. For example, the first dye may have a peak absorption wavelength in a wavelength range of about 585 nm to about 600 nm. The first dye may be a material which absorbs light having a wavelength range of about 585 nm to about 600 nm and transmits light having another wavelength range. However, the peak absorption wavelength of the first dye is not limited to the wavelength range described above, and may have various values. In another embodiment, the first portion O1 may include a first dye which absorbs light having a wavelength range of about 585 nm to about 600 nm, and may further include a second dye which has a peak absorption wavelength in a wavelength range of about 490 nm to about 600 nm and is different from the first dye. The dye included in the first portion O1 may absorb light having a specific wavelength and transmits light having another wavelength range, and may thus prevent reflection of external light and adjust a color of light emitted from the display panel DP.

For example, the first dye included in the first portion O1 may include at least one of an anthraquinone-based compound, a phthalocyanine-based compound, an azo-based compound, a perylene-based compound, a xanthene-based compound, a diimmonium-based compound, a dipyrromethene-based compound, a tetraazaporphyrin-based compound, a porphyrin-based compound, a squarylium-based compound, an oxazine-based compound, a triarylmethane-based compound, and a cyanine-based compound. For example, the first portion O1 may include at least one of a tetraazaporphyrin-based compound, a cyanine-based compound, a squarylium-based compound, and an oxazine-based compound, or a combination thereof.

The first portion O1 may include a first dye in an amount in a range of about 0.01 wt % to about 5.00 wt % with respect to the total weight of the first portion O1. For example, the first portion O1 may include the first dye in an amount in a range of about 0.1 wt % to about 5.00 wt % with respect to the total weight of the first portion O1. In case that the first portion O1 includes the first dye in an amount of less than about 0.01 wt %, the first portion O1 may not sufficiently absorb light having a specific wavelength range, and thus a color gamut may not be improved. In case that the first portion O1 includes the first dye in an amount of greater than about 5.00 wt %, an agglomeration of the first dye may occur.

The second portion O2 may include the first dye. The amount of the first dye included in the second portion O2 may be relatively smaller than the amount of the first dye included in the first portion O1. The second portion O2 may include the first dye in an amount in a range of 0.00 wt % to about 0.01 wt % with respect to the total weight of the second portion O2. The second portion O2 may not include the first dye.

The second portion O2 may include a first material obtained by degrading at least a portion of the first dye. The first material may be an organic material obtained by photodegrading at least a portion of the first dye by ultraviolet rays. The first material may be an organic material having a structure in which at least a portion of the chromophore included in the first dye is destroyed by ultraviolet rays. Accordingly, the first material may have a relatively reduced absorbing ability with respect to visible light, compared to the first dye. For example, the absorbance of the second portion O2 including the first material with respect to visible light may be relatively lower than the absorbance of the first portion O1 including the first dye with respect to visible light. The absorbance of the second portion O2 may be relatively lower than the absorbance of the first portion O1, and thus the display device DD according to an embodiment may achieve an effect of increasing display efficiency for a user to recognize light emitted from the display panel DP.

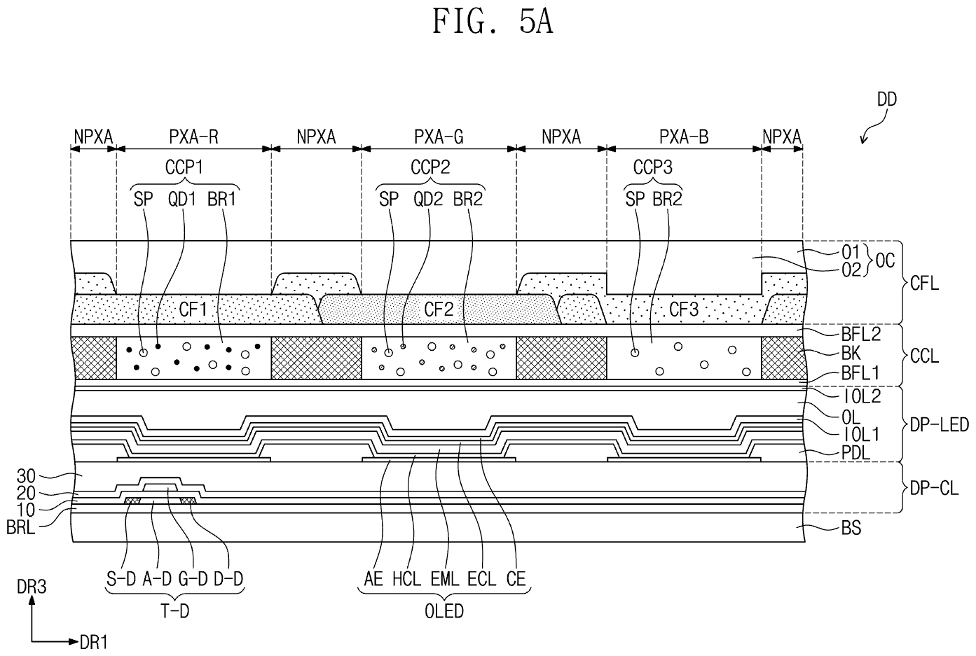

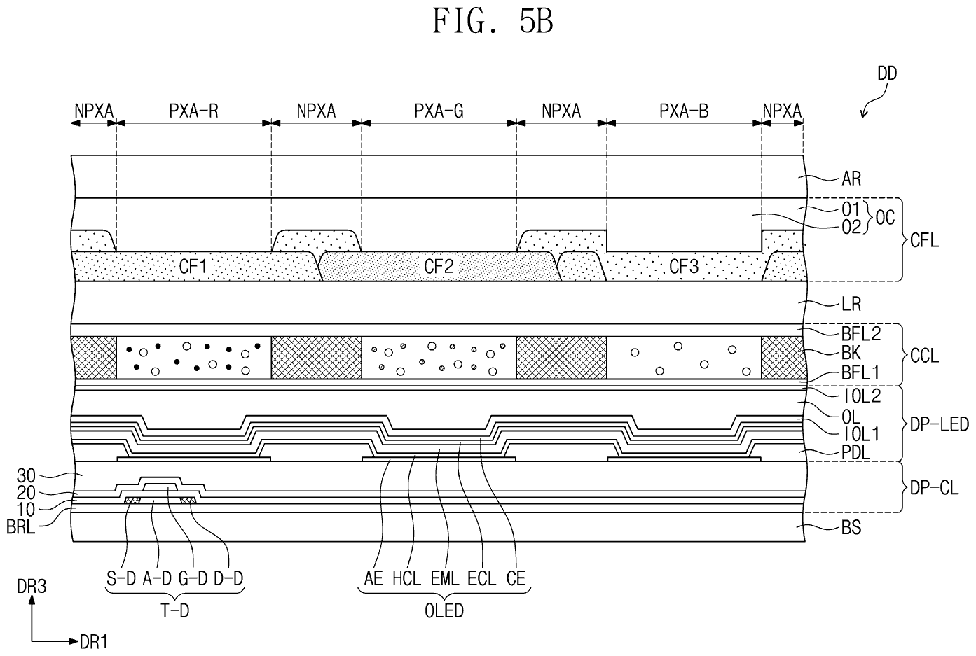

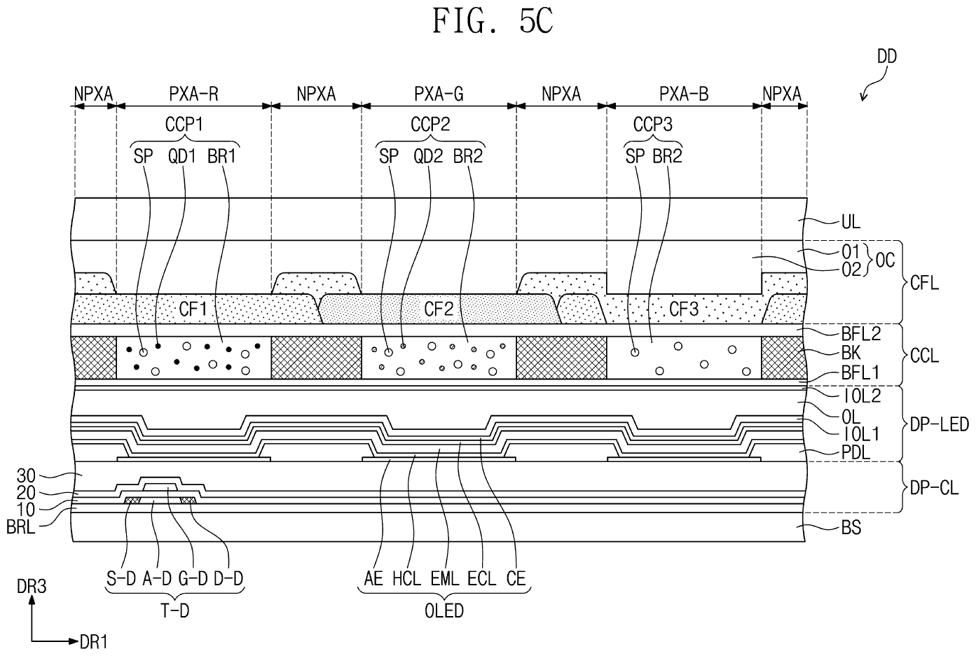

FIGS. 5A to 5C are respectively schematic cross-sectional views of a display device according to embodiments. Hereinafter, components of a display device DD will be described in more detail with the references to FIGS. 5A to 5C. The same reference numerals or symbols are used for the components same as those described above, and a detailed description thereof will be omitted.

Referring to FIG. 5A, a light control layer CCL may include a first light control part CCP1, which includes a first quantum dot QD1 converting the first-color light provided from the light-emitting element OLED into the second-color light, a second light control part CCP2, which includes a second quantum dot QD2 converting the first-color light into the third-color light, and a third light control part CCP3 which transmits the first-color light.

In an embodiment, the first light control part CCP1 may transmit red light which is the second-color light, and the second light control part CCP2 may transmit green light which is the third-color light. The third light control part CCP3 may transmit blue light which is the first-color light provided from the light-emitting element OLED. For example, the first quantum dot QD1 may be a red quantum dot, and the second quantum dot QD2 may be a green quantum dot.

The quantum dots QD1 and QD2 may each have a core-shell structure, and the core of each of the quantum dots QD1 and QD2 may include at least one of a group II-VI compound, a group III-VI compound, a group I-III-VI compound, a group III-V compound, a group IV-VI compound, a group IV element, a group IV compound, and a combination thereof.

The group II-VI compound may include: a binary compound such as CdSe, CdTe, CdS, ZnS, ZnSe, ZnTe, ZnO, HgS, HgSe, HgTe, MgSe, MgS, and a mixture thereof; a ternary compound such as CdSeS, CdSeTe, CdSTe, ZnSeS, ZnSeTe, ZnSTe, HgSeS, HgSeTe, HgSTe, CdZnS, CdZnSe, CdZnTe, CdHgS, CdHgSe, CdHgTe, HgZnS, HgZnSe, HgZnTe, MgZnSe, MgZnS, and a mixture thereof; and a quaternary compound such as HgZnTeS, CdZnSeS, CdZnSeTe, CdZnSTe, CdHgSeS, CdHgSeTe, CdHgSTe, HgZnSeS, HgZnSeTe, HgZnSTe, and a mixture thereof.

The group III-VI compound may include a binary compound such as In₂S₃, In₂Se₃, etc., a ternary compound such as InGaS₃, InGaSe₃, etc., or a combination thereof.

The group I-III-VI compound may include: a ternary compound such as AgInS, AgInS₂, CuInS, CuInS₂, AgGaS₂, CuGaS₂, CuGaO₂, AgGaO₂, AgAIO₂, and a mixture thereof; or a quaternary compound such as AgInGaS₂, CuInGaS₂, and the like.

The group III-V compound may include: a binary compound such as GaN, GaP, GaAs, GaSb, AlN, AIP, AlAs, AlSb, InN, InP, InAs, InSb, and a mixture thereof; a ternary compound such as GaNP, GaNAs, GaNSb, GaPAs, GaPSb, AlNP, AlNAs, AlNSb, AIPAS, AlPSb, InGaP, InAlP, InNP, InNAs, InNSb, InPAs, InPSb, and a mixture thereof; and a quaternary compound such as GaAINP, GaAINAs, GaAINSb, GaAlPAs, GaAlPSb, GaInNP, GaInNAs, GaInNSb, GaInPAs, GaInPSb, InAlNP, InAlNAs, InAlNSb, InAlPAs, InAlPSb, and a mixture thereof. The group III-V compound may further include a group II metal. For example, InZnP, etc., may be selected as the group III-II-V compound.

The group IV-VI compound may include: a binary compound such as SnS, SnSe, SnTe, PbS, PbSe, PbTe, and a mixture thereof; a ternary compound such as SnSeS, SnSeTe, SnSTe, PbSeS, PbSeTe, PbSTe, SnPbS, SnPbSe, SnPbTe, and a mixture thereof; and a quaternary compound such as SnPbSSe, SnPbSeTe, SnPbSTe, and a mixture thereof. The group IV element may include Si, Ge, and a mixture thereof. The group IV compound may include a binary compound such as SiC, SiGe, and a mixture thereof.

The binary compound, the ternary compound, or the quaternary compound may be present in particles with a uniform concentration, or may be present in a same particle in a state in which the concentration thereof is partially non-uniform. Also, the quantum dot may have a core-shell structure in which one quantum dot surrounds another quantum dot. The core-shell structure may have a concentration gradient in which the concentration of an element present in the shell decreases toward the core.

In some embodiments, the quantum dot may have the aforementioned core-shell structure, including a core including nanocrystals, and a shell surrounding the core. The shell of the quantum dot may function as a protective layer for maintaining semiconductor properties by preventing chemical modification of the core and/or a charging layer for imparting electrophoretic properties to the quantum dot. The shell may have a single layer or multiple layers. Examples of the shell of the quantum dot may include a metal oxide, a non-metal oxide, a semiconductor compound, or a combination thereof.

For example, the metal or non-metal oxide may be a binary compound such as SiO₂, Al₂O₃, TiO₂, ZnO, MnO, Mn₂O₃, Mn₃O₄, CuO, FeO, Fe₂O₃, Fe₃O₄, CoO, Co₃O₄, NiO, etc., or a ternary compound such as MgAl₂O₄, CoFe₂O₄, NiFe₂O₄, CoMn₂O₄, etc., but the disclosure is not limited thereto.

An example of the semiconductor compound may include CdS, CdSe, CdTe, ZnS, ZnSe, ZnTe, ZnSeS, ZnTeS, GaAs, GaP, GaSb, HgS, HgSe, HgTe, InAs, InP, InGaP, InSb, AlAs, AlP, AlSb, etc., but the disclosure is not limited thereto.

The quantum dots QD1 and QD2 may each have, in a light-emission wavelength spectrum, a full width of half maximum (FWHM) of less than or equal to about 45. For example, the quantum dots QD1 and QD2 may each have, in a light-emission wavelength spectrum, a full width of half maximum (FWHM) of less than or equal to about 40 nm. For example, the quantum dots QD1 and QD2 may each have, in a light-emission wavelength spectrum, a full width of half maximum (FWHM) of less than or equal to about 30 nm. Within this range, a color purity or color gamut may be improved. Light emitted through the quantum dots QD1 and QD2 is emitted in all directions, and thus a wide viewing angle may be improved.

Also, shapes of the quantum dots QD1 and QD2 are not particularly limited to a shape generally used in the art, and the quantum dots QD1 and QD2 may have a spherical shape, pyramidal shape, multi-arm shape, cubic nanoparticle, nanotube, nanowire, nanofiber, nanoplate-shaped particle, or the like.

Sizes of the quantum dots QD1 and QD2 may be adjusted or an element ratio of compounds of the quantum dots QD1 and QD2 may be adjusted, and thus, the quantum dots may have various light-emission colors such as blue, red, and green. For example, the adjustment of the sizes of the quantum dots QD1 and QD2 or an element ratio of the compounds of the quantum dots QD1 and QD2 may be selected such that red, green and/or blue light is emitted. In an embodiment, the quantum dot QD1 included in the first light control part CCP1 in the first light-emitting region PXA-R may have a red light-emission color, and the quantum dot QD2 included in the second light control part CCP2 in the second light-emitting region PXA-G may have a green light-emission color. As the quantum dots QD1 and QD2 have smaller particle sizes, light having a shorter wavelength range may be emitted. For example, the particle sizes of the quantum dots QD1 and QD2 which each have the same core and emit green light may be smaller than the particle size of the quantum dot which emits red light. The particle sizes of the quantum dots QD1 and QD2 which have the same core and emit blue light may be smaller than the particle size of the quantum dot that emits green light. However, the disclosure is not limited thereto, and the particle sizes of the quantum dots QD1 and QD2, although having the same core, may be adjusted depending on a shell-forming material, a shell thickness, or the like.

In case that the quantum dots QD1 and QD2 have various light-emission colors such as blue, red, and green, the quantum dots having different light-emission colors may have different core materials.

The light control layer CCL may further include a scatterer SP. The first light control part CCP1 may include the first quantum dot QD1 and the scatterer SP, and the second light control part CCP2 may include the second quantum dot QD2 and the scatterer SP, and the third light control part CCP3 may not include a quantum dot but include the scatterer SP.

The scatterer SP may be an inorganic particle. For example, the scatterer SP may include at least one of TiO2, ZnO, Al2O3, SiO2, and hollow silica. The scatterer SP may include at least one of TiO2, ZnO, Al2O3, SiO2, and hollow silica, or may be a mixture of two or more materials of TiO2, ZnO, Al2O3, SiO2, and hollow silica.

The first light control part CCP1, the second light control part CCP2, and the third light control part CCP3 may respectively include base resins BR1, BR2, and BR3 in which the quantum dots QD1 and QD2 and the scatterer SP are dispersed. In an embodiment, the first light control part CCP1 may include a first quantum dot QD1 and the scatterer SP dispersed in a first base resin BR1, the second light control part CCP2 may include a second quantum dot QD2 and the scatterer SP dispersed in a second base resin BR2, and the third light control part CCP3 may include the scatterer SP dispersed in a third base resin BR3. The base resins BR1, BR2, and BR3 may be a medium in which the quantum dots QD1 and QD2 and the scatterer SP are dispersed, and may be composed of a resin composition generally referred to as a binder. For example, the base resins BR1, BR2, and BR3 may be an acylate-based resin, a urethane-based resin, a silicone-based resin, an epoxy-based resin, or the like. The base resins BR1, BR2, and BR3 may be transparent. In an embodiment, the first base resin BR1, the second base resin BR2, and the third base resin BR3 may be the same or different from each other.

Referring to FIG. 5B, the display device DD according to an embodiment may further include an anti-reflective layer AR disposed on a color filter layer CFL. The anti-reflective layer AR may include a high-refractive-index layer and a low-refractive-index layer. For example, the anti-reflective layer AR may have a structure in which the high-refractive-index layer and the low-refractive-index layer are alternately stacked each other. The anti-reflective layer AR may include at least one of Si₃N₄, SiNₓ, SiO₂, Al₂O₃, Nb₂O₅, AlN, SiO, AlOₓN_{y}, SiOₓN_{y}, SiᵤAlᵥOₓN_{y}, MgF₂, MgO, TiO₂, GeO₂, MgAl₂O₄, BaF₂, CaF₂, DyF₃, YbF₃, YF₃, CeF₃, Ta₂O₅, HfO₂, ZrO₂, MoO₃, and a combination thereof. Since the display device DD according to an embodiment further includes the anti-reflective layer AR, reflection of external light may be reduced, and thus display efficiency may be improved.

The display device DD according to an embodiment may further include a low-refractive-index layer LR between the light control layer CCL and the color filter layer CFL. The low-refractive-index layer LR may have a lower refractive index than the color filter layer CFL and the light control layer CCL which are adjacent thereto. The low-refractive-index layer LR may totally reflect portion of blue light emitted from the light control layer CCL toward the color filter layer CFL, and allow the light to re-enter the light control layer CCL. The blue light may be emitted from the light-emitting element OLED. The portion of the blue light may be re-entered into the first light control part CCP1 or the second light control part CCP2 which is included in the light control layer CCL. As described above, the first light control part CCP1 may change the re-entered blue light into red light, and the second light control part CCP2 may change the re-entered blue light into green light. Such light recirculation may improve the light efficiency of the display device DD.

Referring to FIG. 5C, the display device DD according to an embodiment may further include an ultraviolet ray blocking layer UL disposed on the color filter layer CFL. The ultraviolet ray blocking layer UL may block light having a wavelength range of less than or equal to about 450 nm. The ultraviolet ray blocking layer UL may block ultraviolet rays to reduce the amount of light incident onto the second portion O2 of the color filter layer CFL. The ultraviolet ray blocking layer UL may include at least one of a light absorber and a light stabilizer with respect to ultraviolet rays. The ultraviolet ray blocking layer UL may include, as a light absorber, a benzophenone-based compound, a benzotriazole-based compound, or a triazine-based compound, and may include tetramethyl piperidine, etc., as a light stabilizer. However, a material included in the ultraviolet ray blocking layer UL is not limited thereto, and the ultraviolet ray blocking layer UL may include another material which functions to block light having a wavelength range of less than or equal to about 450 nm.

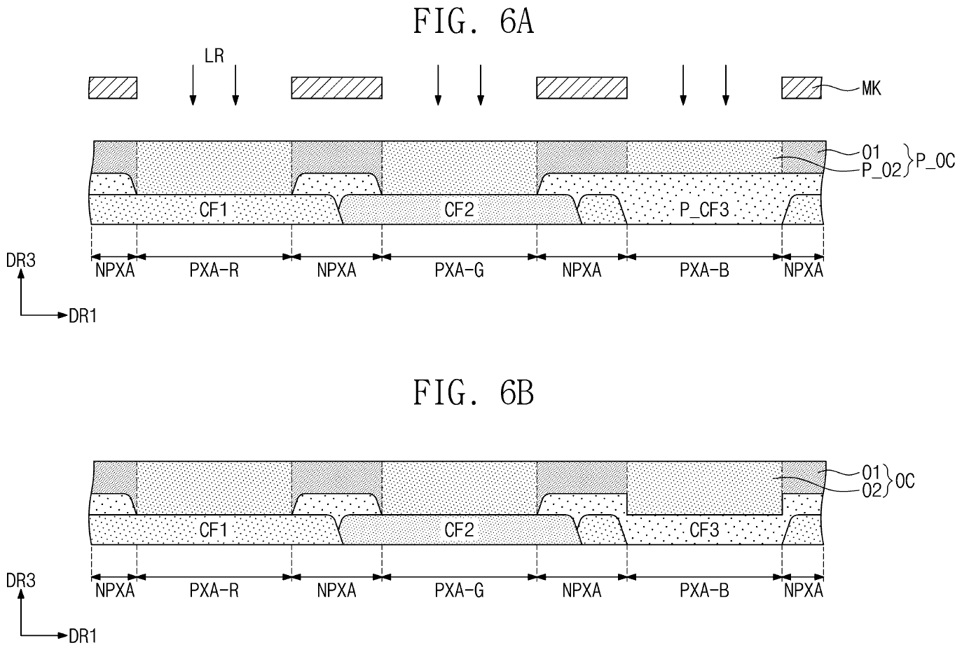

Hereinafter, a method of manufacturing a display device according to an embodiment of the disclosure will be described with reference to FIGS. 6A and 6B.

FIGS. 6A and 6B are schematic cross-sectional views sequentially illustrating operations of the method of manufacturing the display device according to an embodiment of the disclosure. FIGS. 6A and 6B schematically illustrate a method of forming an overcoat layer OC in the method of manufacturing the display device DD according to an embodiment of the disclosure. In the description of the method of manufacturing the display device according to an embodiment of the disclosure, the same reference numerals or symbols are used for the components same as those described above, and a detailed description thereof will be omitted.

Referring to FIG. 6A, the method of manufacturing the display device according to an embodiment of the disclosure may include forming a preliminary overcoat layer P_OC on first and second filters CF1 and CF2 in a first light-emitting region PXA-R and a second light-emitting region PXA-G, and on a preliminary third filter P_CF3 in a third light-emitting region PXA-B. The preliminary third filter P_CF3 in the third light-emitting region PXA-B may have a relatively greater height than the first and second filters CF1 and CF2 in the first light-emitting region PXA-R and the second light-emitting region PXA-G. The preliminary third filter P_CF3 in a non-light-emitting region NPXA may be disposed on the first and second filters CF1 and CF2. The preliminary overcoat layer P_OC may include a first portion O1 in the non-light-emitting region NPXA and a preliminary second portion P_O2 in the light-emitting regions PXA-R, PXA-G, and PXA-B. The first portion O1 and the preliminary second portion P_O2 of the preliminary overcoat layer P_OC may be integrally formed from a same material and through a same process at the same time.

Referring FIGS. 6A and 6B, the method of manufacturing the display device according to an embodiment of the disclosure may include forming a second portion O2 by irradiating the preliminary second portion P_O2 with ultraviolet rays UV. The forming of the second portion O2 may include irradiating the overcoat layer OC in the light-emitting regions PXA-R, PXA-G, and PXA-B with the ultraviolet rays UV. The second portion O2 may include a first material obtained by degrading at least a portion of a first dye included in the preliminary second portion P_O2 by the ultraviolet rays UV. Accordingly, the weight percent of the first dye of the first portion O1 may be relatively greater than the weight percent of the second portion O2. The irradiating of the preliminary second portion P_O2 with the ultraviolet rays UV may include forming a third filter CF3 by degrading at least a portion of the preliminary third filter CF3. For example, the preliminary third filter P_CF3 may include a blue dye, and at least a portion of the blue dye in the preliminary third filter P_CF3 in the third light-emitting region PXA-B may be degraded by irradiation of the ultraviolet rays UV. Accordingly, the heights of the first and second filters CF1 and CF2 and the third filter CF3 may substantially be the same.

Hereinafter, evaluation results of characteristics of a display device according to an embodiment of the disclosure will be described with reference to the above-described drawings, Example, and Comparative examples. Example to be illustrated below is described as an example for ease of understanding the disclosure, and the scope of the disclosure is not limited thereto.

### (Manufacture of Display Device)

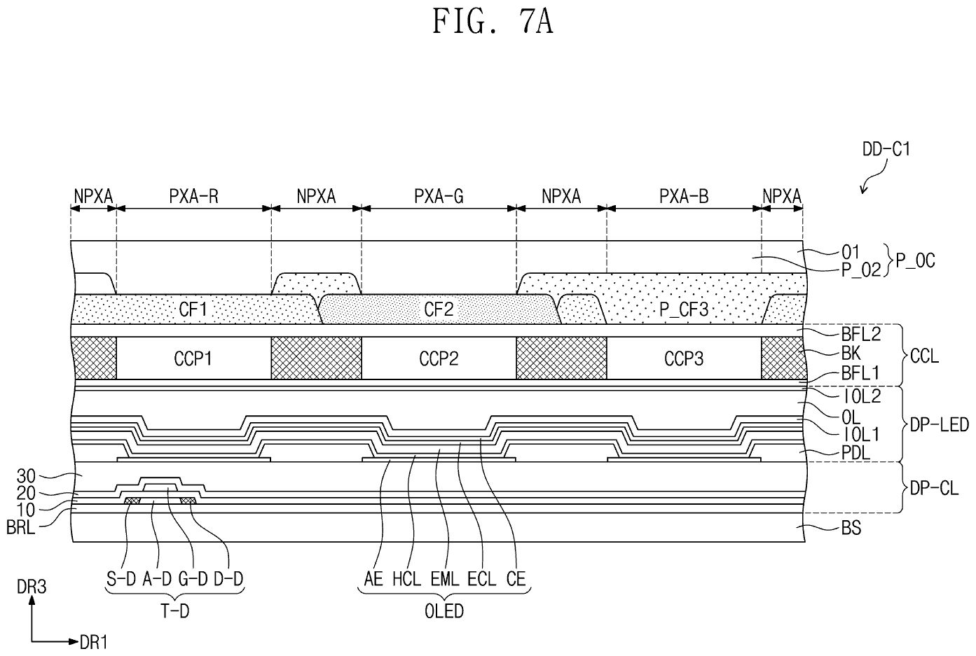

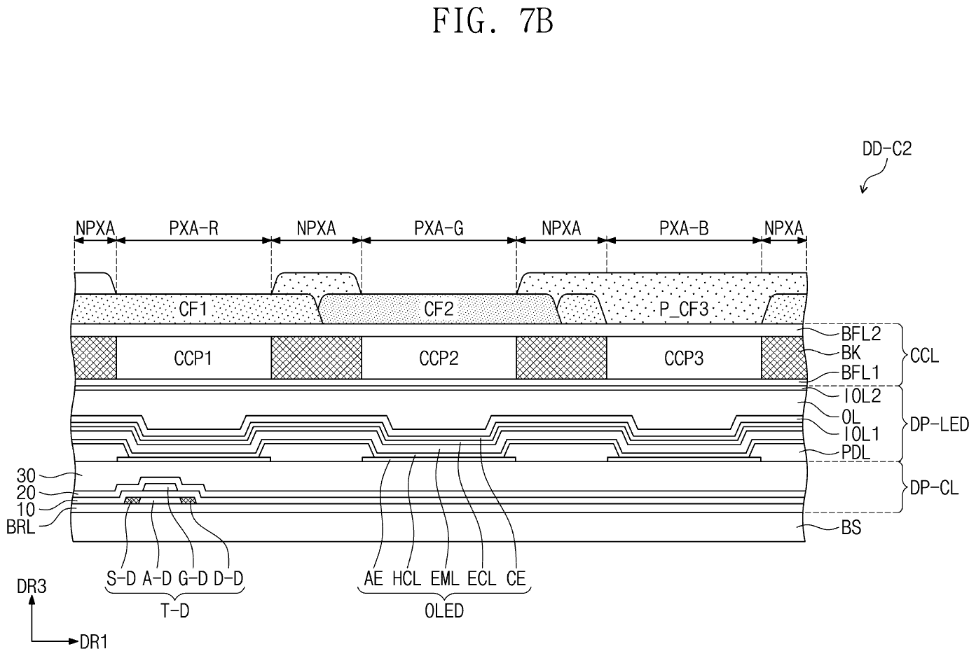

Display devices of Example and Comparative Examples 1 and 2 to be described below were all manufactured to have a same structure except for a color filter layer. For example, the display device of Example was manufactured to have a structure of the display device DD in FIG. 3 including the first to third filters CF1, CF2, and CF3 and the overcoat layer OC. The display device of Comparative Example 1 was manufactured to have a structure of the display device DD-C1 in FIG. 7A including the first and second filters CF1 and CF2, the preliminary third filter P_CF3, and the preliminary overcoat layer P_OC. Compared to the display device of Comparative Example 1, the display device of Comparative Example 2 was manufactured to have a structure of the display device DD-C2 in FIG. 7B not including the preliminary overcoat layer P_OC and including only the first and second filters CF1 and CF2 and the preliminary third filter P_CF3.

### (Evaluation of Display Device)

FIG. 8 is a graph showing light transmittance values of the display devices according to Example and Comparative Example 1. FIG. 8 shows a light transmittance value versus a wavelength range in the light-emitting regions PXA-R, PXA-G, and PXA-B of the display devices according to Example and Comparative Example 1. Referring to FIG. 8, it may be confirmed that compared to Comparative Example 1, the display devices according to Example has a greater transmittance value with respect to light having a visible light wavelength in the light-emitting regions PXA-R, PXA-G, and PXA-B. It may be confirmed that in Comparative Example, a transmittance value with respect to light having a wavelength range of about 580 nm to about 600 nm is relatively lower than light with respect to light having other wavelength ranges.

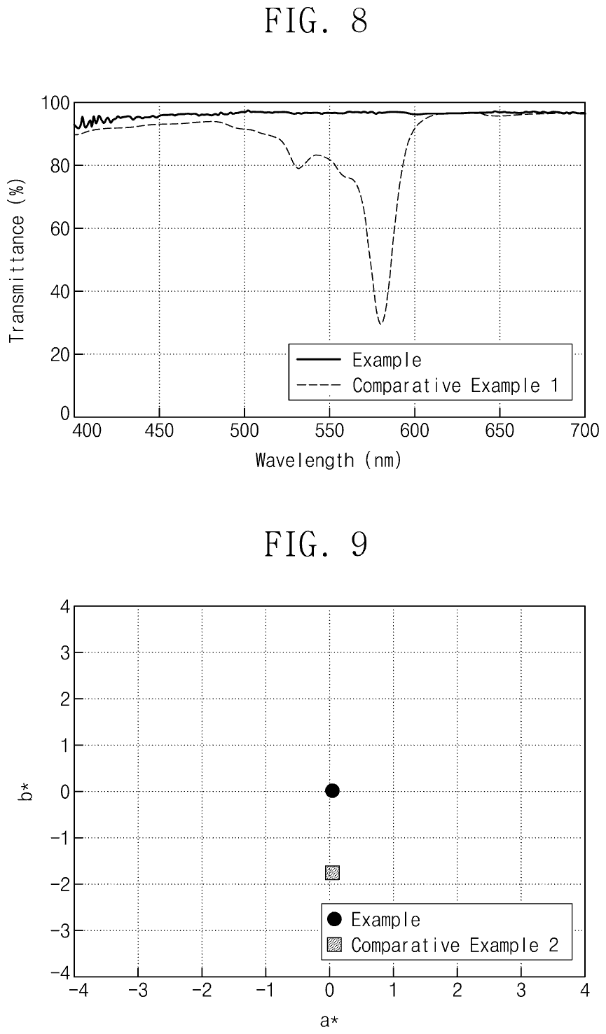

FIG. 9 is a graph showing color coordinates for the devices of Example and Comparative Example 2 according to a CIE1931 standard colorimetric system. FIG. 9 shows an average value of color coordinates for the devices of Example and Comparative Example 2. Referring to FIG. 9, it may be confirmed that compared to Comparative Example 2, in the display device according to Example, light emitted from the light-emitting element OLED is more white. For example, it may be confirmed that in the display device according to Example, light having relatively higher purity is emitted in a white wavelength region.

A display device according to an embodiment of the disclosure may include an overcoat layer including a first dye, and the overcoat layer may include a portion including the first dye in a different amount of a weight percent. For example, in the display device according to an embodiment, the proportion of the first dye in the overcoat layer in the non-light-emitting region may be relatively higher than the overcoat layer in the light-emitting region. The overcoat layer in the light-emitting region may include a first material obtained by degrading at least a portion of the first dye by ultraviolet rays.

A typical display device includes, on a light-emitting element, an optical member containing, a dye to reduce reflection of external light. However, in case that a dye which functions to absorb visible light is included, light transmittance and display efficiency may be reduced. A typical display device includes, on a light-emitting element, multiple color filters to increase a color gamut and reduce reflection of external light. However, as a third filter having a blue color occupies a relatively greater area than first and second filters which respectively have red and green colors, there is a limitation in that emitted light appears blue. According to the disclosure, not only an effect of whitening emitted light may be achieved by disposing an overcoat layer including a first dye on a color filter, but also effects of increasing display efficiency and reducing reflection of external light may be satisfactorily achieved by allowing the overcoat layer in a light-emitting region to include a first material obtained by degrading the first dye. For example, an overcoat layer may include a dye, and thus the quality of light to be emitted may be improved. Also, the overcoat layer in a light-emitting region may include a dye the light absorption ability of which is decreased, compared to the overcoat layer in the non-light-emitting region, and thus light transmittance and color gamut may be improved. Therefore, since the display device according to an embodiment of the disclosure includes an overcoat layer including a dye and also the overcoat layer in the light-emitting region has a relatively lower absorbance, emitted light quality and display efficiency may be improved, and thus the display device with improved reliability may be provided.

In a display device according to an embodiment of the disclosure, a material included in an overcoat layer may vary according to a pixel region and a non-pixel region. Therefore, the display device including the overcoat layer according to an embodiment of the disclosure may have improved light efficiency and reduced reflection of external light.

The above description is an example of technical features of the disclosure, and those skilled in the art to which the disclosure pertains will be able to make various modifications and variations. Therefore, the embodiments of the disclosure described above may be implemented separately or in combination with each other.

Therefore, the embodiments disclosed in the disclosure are not intended to limit the technical spirit of the disclosure, but to describe the technical spirit of the disclosure, and the scope of the technical spirit of the disclosure is not limited by these embodiments. The protection scope of the disclosure should be interpreted by the following claims, and it should be interpreted that all technical spirits within the equivalent scope are included in the scope of the disclosure.

What is claimed is:

1. A display device comprising:
a display panel divided into a light-emitting region which emits light, and a non-light-emitting region adjacent to the light-emitting region; and
an overcoat layer disposed on the display panel,
wherein the overcoat layer includes:
a first portion overlapping the non-light-emitting region in a plan view and including a first dye; and
a second portion overlapping the light-emitting region in a plan view and including a first material obtained by degrading at least a portion of the first dye.

2. The display device of claim 1, wherein the first material is obtained by photodegrading at least a portion of the first dye by ultraviolet rays.

3. The display device of claim 2, wherein
the first dye comprises a chromophore, and
the first material is obtained by destroying at least a portion of the chromophore by the ultraviolet rays.

4. The display device of claim 1, wherein an absorbance of the first portion is greater than an absorbance of the second portion with respect to visible light.

5. The display device of claim 1, wherein a weight percent of the first dye with respect to a total weight of the first portion is in a range of about 0.1 wt % to about 5 wt %.

6. The display device of claim 1, wherein the first dye has an absorption wavelength peak in a range of about 530 nm to about 600 nm.

7. The display device of claim 1, wherein the first dye comprises at least one of an anthraquinone-based compound, a phthalocyanine-based compound, an azo-based compound, a perylene-based compound, a xanthene-based compound, a diimmonium-based compound, a dipyrromethene-based compound, a tetraazaporphyrin-based compound, a porphyrin-based compound, a squarylium-based compound, an oxazine-based compound, a triarylmethane-based compound, and a cyanine-based compound.

8. The display device of claim 1, wherein the overcoat layer has a thickness in a range of about 1 μm to about 15 μm.

9. The display device of claim 1, wherein the overcoat layer further includes a pigment.

10. The display device of claim 9, wherein a weight percent of the pigment with respect to a total weight of the overcoat layer is in a range of about 1 wt % to about 50 wt %.

11. The display device of claim 1, further comprising:
an ultraviolet ray blocking layer disposed on the overcoat layer and overlapping the non-light-emitting region in a plan view.

12. The display device of claim 11, wherein the ultraviolet ray blocking layer comprises a light absorber or a light stabilizer with respect to ultraviolet rays.

13. The display device of claim 1, wherein
the display panel comprises a light-emitting element that emits first-color light,
the light-emitting region comprises a first light-emitting region, a second light-emitting region, and a third light-emitting region which are spaced apart from each other in a plan view,
the first light-emitting region emits second-color light different from the first-color light,
the second light-emitting region emits third-color light different from the first-color light and the second-color light, and
the third light-emitting region transmits the first-color light.

14. The display device of claim 13, further comprising:
a light control layer disposed between the display panel and the overcoat layer,
wherein the light control layer includes:
a first light control part that overlaps the first light-emitting region in a plan view and converts the first-color light into the second-color light; and
a second light control part that overlaps the second light-emitting region in a plan view and converts the first-color light into the third-color light.

15. The display device of claim 14, further comprising:
a color filter layer disposed between the display panel and the light control layer,
wherein the color filter layer includes:
a first filter that overlaps the first light-emitting region in a plan view and blocks the first-color light and the third-color light;
a second filter that overlaps the second light-emitting region in a plan view and blocks the first-color light and the second-color light; and
a third filter that overlaps the third light-emitting region in a plan view and blocks the second-color light and the third-color light.

16. The display device of claim 15, wherein the third filter entirely overlaps the non-light-emitting region in a plan view.

17. The display device of claim 15, wherein in a plan view, the first filter does not overlap the second filter.

18. The display device of claim 15, further comprising:
a low-refractive-index layer disposed between the light control layer and the color filter layer; and
an anti-reflection layer disposed on the color filter layer.

19. A display device comprising:
a display panel divided into a light-emitting region which emits light and a non-light-emitting region adjacent to the light-emitting region; and
an overcoat layer disposed on the display panel, and including a first portion overlapping the non-light-emitting region in a plan view and a second portion overlapping the light-emitting region in a plan view, wherein
the overcoat layer includes a first dye, and
a weight percent of the first dye with respect to a total weight of the first portion is greater than a weight percent of the first dye with respect to a total weight of the second portion.

20. The display device of claim 1, wherein the weight percent of the first dye with respect to the total weight of the second portion is less than or equal to about 0.1 wt %.
